(19) United States
(12) Patent Application Publication
(10) Pub. No.: US 2006/0226452 A1
(43) Pub. Date: Oct. 12, 2006

(54) Solid-state image pickup device and the manufacture method thereof

(75) Inventor: Susumu Yamaguchi, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KONICA MINOLTA OPTO, INC.

(21) Appl. No.: 11/397,701

(22) Filed: Apr. 5, 2006

(30) Foreign Application Priority Data
Apr. 8, 2005 (JP) 2005-111864

(51) Int. Cl. H01L 27/148

(52) U.S. Cl. 257/231

(57) ABSTRACT

A solid-state image pickup device includes: a photoelectric conversion section formed on one face of a silicon substrate, a seal member for sealing the photoelectric conversion section, and an electrode for sending and receiving an electric signal, wherein the seal member comprises an image pickup lens section for causing the photoelectric conversion section to form an object image; and the electrode is formed on a face different from the one face of the silicon substrate.

### BACKGROUND OF THE INVENTION

1. Technical Field of the Invention

The present invention relates to a solid-state image pickup device and the manufacture method thereof. In particular, the present invention relates to a solid-state image pickup device having superior productivity and the manufacture method thereof.

2. Description of Related Art

Recently, portable phones including image pickup apparatuses have been increasingly used with the advent of smaller and more sophisticated image pickup apparatuses using CCD (Charged Coupled Device)-type or CMOS (Complementary Metal Oxide Semiconductor)-type solid-state image pickup devices. Image pickup lenses included in these image pickup apparatuses also have been required to have a further smaller size.

Furthermore, a portable phone including at least one of two different image pickup apparatuses has been recently sold. One of these image pickup apparatuses is a solid-state image pickup device having a great number of pixels (e.g., two million pixels or more) and is mainly used to photograph a still image. The other of these image pickup apparatuses is an image pickup apparatus for a video phone application that sends, on a real-time basis, a moving picture taken by a portable phone of one party to another portable phone of the other party. Thus, this image pickup apparatus has a limited amount of data transfer and thus includes a solid-state image pickup device having a limited number of pixels (e.g., 100,000 to 300,000 pixels). It has been strongly desired that the latter image pickup apparatus can be manufactured with a simple structure and with a low cost.

An example of an image pickup apparatus for such an application is disclosed, for example, by Japanese Patent Unexamined Publication No. 2003-37758. Japanese Patent Unexamined Publication No. 2003-46825 discloses an image pickup lens having three lenses that has superior productivity.

However, the image pickup apparatus described in Japanese Patent Unexamined Publication No. 2003-37758 causes, when using the recent solid-state image pickup device having a small pixel pitch, the respective components to be excessively small, which may cause a possibility where the manufacture is difficult despite of the purpose. Specifically, the recent technique has enabled even a CMOS-type solid state image pickup device to have a significantly small pixel pitch of 2.2 μm. When this pixel pitch is used in a solid-state image pickup device having 100,000 pixels, a rectangular effective pixel region of 352 pixels (horizontal)×288 pixels (vertical) has a diagonal line length of 1.0 mm. When assuming that a diagonal field angle is 60 degrees and a focal distance is f[mm], then the result is as follows.

f×tan 30 degrees=0.5 mm (i.e., f=0.87 mm)

(As well, this formula doesn't consider distortion aberration.) Thus, an image pickup lens having a significantly small focal distance is required.

Furthermore, although the image pickup lens having the structure of three lenses as described in Japanese Patent Unexamined Publication No. 2003-46825 has a superior optical characteristic, this structure requires troublesome manufacture because the respective lenses must be molded individually. On the other hand, an image pickup of a small image having a limited number of pixels of about 100,000 for example cannot provide a high-quality image even when an image pickup lens having a high optical characteristic is used.

### SUMMARY OF THE INVENTION

The present invention has been made in view of the problems as described above. It is an objective of the present invention to provide, based on a concept different from that of the conventional technique, an image pickup lens-integrated solid state image pickup device having superior productivity.

In accordance with the first aspect of the present invention, a solid-state image pickup device comprising:

a photoelectric conversion section formed on one face of a silicon substrate, a seal member for sealing the photoelectric conversion section, and an electrode for sending and receiving an electric signal,

wherein the seal member comprises an image pickup lens section for causing the photoelectric conversion section to form an object image; and

the electrode is formed on a face different from the one face of the silicon substrate.

In the solid-state image pickup device according to the first aspect of the present invention, the seal member has the image pickup lens section. Thus, the solid-state image pickup device itself has a function as an image pickup apparatus and an image pickup apparatus having a simple structure can be structured. The photoelectric conversion section is formed on a face different from the one face of the silicon substrate (a face different from the face on which the photoelectric conversion section is formed). This can reduce the mounting area of an image pickup device when the image pickup device is mounted on an electronic substrate (a project area of the solid-state image pickup device to the electronic substrate).

The seal member is preferably provided on the silicon substrate via a spacer member provided around the photoelectric conversion section.

In this case, the photoelectric conversion section can be sealed without requiring the seal member to have a complicated shape.

The seal member is preferably integrated with an aperture stop and/or an infrared ray cut filter coating.

In this case, the seal member having the image pickup lens section is integrated with the aperture stop and the infrared ray cut filter. Thus, an image pickup lens-integrated solid state image pickup device having superior productivity can be provided. Consequently, the use of the solid-state image pickup device can reduce the size of the image pickup apparatus.

The expression “integrated” means to include any of a method for forming the aperture stop and the infrared ray cut filter coating as a coating on the seal member by a coating method (e.g., vacuum deposition) and a method for fixing them as separate members.

The solid-state image pickup device according to the first aspect of the present invention is preferably manufactured by simultaneously forming a plurality of solid-state image pickup devices on the silicon substrate to subsequently subject the devices to a dicing step to separate the devices as chips.

In this case, when the solid-state image pickup devices are cut out by the dicing step, the image pickup lenses are already mounted. This allows the solid-state image pickup devices to be manufactured in a large amount.

The seal member preferably has a glass transition temperature Tg of 200° C. or more.

In the field of electronic components, electric appliances recently have a smaller size and a higher performance. Thus, the surface-mount technology (SMT), which has a high density at which components are mounted and has a high efficiency, has been increasingly used as a method for improving the productivity and for mounting various electronic components on a substrate. The surface-mount method herein means a method for arranging an electronic component on a printed wiring substrate for example via creamy solder to subsequently subject the wiring substrate to a heating furnace (reflow furnace) to fuse the solder to fix the electronic component on the wiring substrate. During the soldering, the wiring substrate and the electronic component in the reflow furnace have a temperature as high as 200 to 270° C.

In order to mount the solid-state image pickup device according to the first aspect of the present invention on the substrate by this reflow solder, at least the seal member having the image pickup lens section requires heat resistance to the reflow. Thus, the seal member having the image pickup lens desirably has a glass transition temperature Tg of 200° C. or more. The glass transition temperature Tg lower than 200° C. causes a significant change in the characteristic of the image pickup lens section of the seal member. The seal member cannot maintain the original image formation performance. In order to avoid the change of the characteristic under a high temperature in the reflow furnace in particular, the seal member must have the glass transition temperature Tg of 200° C. or more. When the seal member has the glass transition temperature Tg of 270° C. or more, the heat resistance is higher and thus is desirable.

The seal member having the image pickup lens section may be made of glass material or resin material. Recently, even optical resin material having Tg of 200° C. or more has been disclosed (see Japanese Patent Unexamined Publication No. 2004-4632 for example).

In accordance with the second aspect of the present invention, a method for manufacturing a plurality of solid-state image pickup devices, each of the solid-state image pickup devices comprising a photoelectric conversion section, an image pickup lens section for causing the photoelectric conversion section to form an object image and an electrode for sending and receiving an electric signal, comprising:

forming a plurality of the photoelectric conversion sections on one face of a silicon substrate;

forming the electrode on a face different from the one face of the silicon substrate;

forming seal members having a plurality of the image pickup lens sections, via lattice-shaped spacer members provided around each of the photoelectric conversion sections, on the one face of the silicon substrate so as to seal the photoelectric conversion sections; and

cutting the silicon substrate, the spacer members and the seal members which are integrated, at the lattice frames of the spacer members.

According to the manufacture method of the solid-state image pickup device according to the second aspect of the present invention, when the silicon substrate, the spacer members and the seal members are cut out by the cutting/separation step (e.g., dicing step), the photograph lens sections are already mounted so as to correspond to the photoelectric conversion sections. Thus, the devices can be manufactured in a large amount.

Since the electrode is formed on a face different from the one face of the seal member (a face on which the photoelectric conversion section is formed), a mounting area to the electronic substrate (project area to the substrate) can be reduced.

Furthermore, in the cutting/separation step, the silicon substrate, the spacer members and the seal members are cut at the lattice frames of the lattice-shaped spacer members. Thus, when individual image pickup devices are separated, spacer members are formed by the cut lattices, and the spacers are easily provided.

The second aspect of the present invention preferably comprises forming a coating of infrared ray cut filters on the seal members.

In this case, separate infrared ray cut filter members need not be provided, and they are easily handled.

The second aspect of the present invention preferably comprises forming a film having a light blocking property at an exterior of an aperture stop on the seal members.

In this case, the simple structure can prevent unnecessary light from being incident on the photoelectric conversion section and provides the positioning accurately.

In the first and second aspects of the present invention, it is preferable that the image pickup lens section has an aspheric surface shape in which a face closest to an object has a convex surface toward the object and the other faces have a flat surface shape.

In this case, an intersection point of the object side face of the image pickup lens section and the optical axis of the image pickup lens section functions as a principal point position. Thus, the principal point position can be away from the photoelectric conversion section, thus reducing the height of the solid-state image pickup device. Furthermore, the other faces except for the object side face of the image pickup lens section have a flat surface shape. Thus, a manufacture method for forming an image pickup lens section by using a glass substrate as base material for the parallel flat plate can be used. This is preferable because the above method provides an easier manufacture than a manufacture method for forming an image pickup lens section having a plurality of curved surfaces. Furthermore, only one face of the object side face has a refracting power. Thus, in order to provide favorable aberration correction, the object side face of the image pickup lens section preferably has an aspheric surface shape.

### BRIEF DESCRIPTION OF THE DRAWINGS

The present invention will become more fully understood from the detailed description given below and the accompanying drawings which are given by way of illustration only, and thus are not intended to limit the scope of the invention, and wherein:

FIG. 1 is a cross-sectional view illustrating a solid-state image pickup device attached with a lens;

FIG. 2 illustrates manufacture steps (the former stage) of the solid-state image pickup device;

FIG. 3 illustrates manufacture steps (the latter stage) of the solid-state image pickup device;

FIG. 4 illustrates a modified embodiment (Modified Embodiment 1) of the solid-state image pickup device of FIG. 1;

FIG. 5 illustrates a modified embodiment (Modified Embodiment 2) of the solid-state image pickup device of FIG. 1;

FIG. 6 illustrates a spherical aberration of an image pickup lens section according to Exemplary Example 1;

FIG. 7 illustrates astigmatism of the image pickup lens section according to Exemplary Example 1;

FIG. 8 illustrates distortion aberration of the image pickup lens section according to Exemplary Example 1;

FIG. 9 illustrates spherical aberration of an image pickup lens section according to Exemplary Example 2;

FIG. 10 illustrates astigmatism of the image pickup lens section according to Exemplary Example 2; and

FIG. 11 illustrates distortion aberration of the image pickup lens section according to Exemplary Example 2.

### PREFERRED EMBODIMENT OF THE INVENTION

Hereinafter, embodiments of the present invention will be described with reference to the drawings.

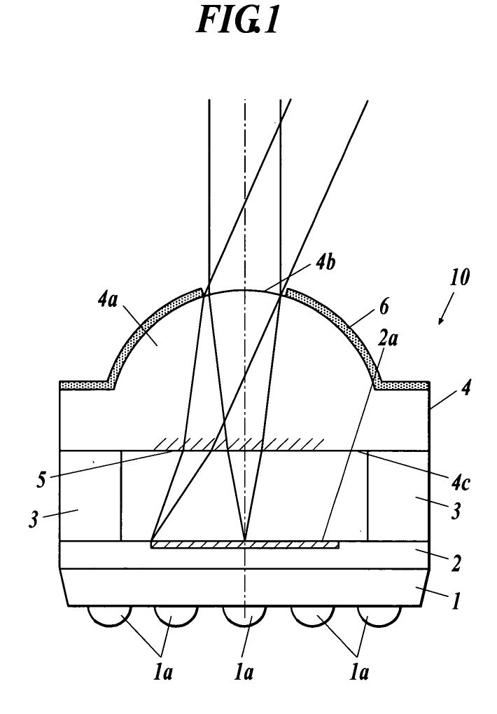

FIG. 1 is a cross-sectional view illustrating an image pickup lens-integrated solid-state image pickup device 10 according to this embodiment.

In FIG. 1, the solid-state image pickup device 10 has an integral structure of a silicon substrate 1 having a plurality of electrodes 1a, a semiconductor device 2 which is formed on the silicon substrate 1 and has a photoelectric conversion section 2a, a spacer member 3 provided on the upper face of the semiconductor device 2 around the photoelectric conversion section 2a, and a plate-like seal member 4 which is supported by the upper end of the spacer member 3 and has an image pickup lens section 4a at the center. The seal member 4 seals the photoelectric conversion section 2a and has a function for protecting the photoelectric conversion section 2a and a function for forming an image. The seal member 4 has a glass transition temperature Tg of 200° C. or more.

The electrode 1a is formed on a face that is different from a face of the silicon substrate 1 on which the photoelectric conversion section 2a is provided. The photoelectric conversion section 2a includes photoelectric conversion devices (pixels) arranged in a two-dimensional manner on which R (red), G (green), and B (blue) primary color transmission filter layers and a microlens array corresponding to the respective photoelectric conversion devices (not shown) are layered.

The image pickup lens section 4a of the seal member 4 has the optical surface 4b for allowing the photoelectric conversion section 2a to form an object image at a predetermined subject distance. The image pickup lens section 4a has the optical surface 4b having an aspheric surface shape in which a face closest to an object is convexed toward the object. (The optical surface 4b also may have a spherical surface shape.) The other faces other than the optical surface 4b have a flat surface. In order to allow the photoelectric conversion section 2a to form an image with a high accuracy, a curvature radius of the optical surface 4b or a thickness of the seal member 4 are controlled with a high accuracy.

The image pickup lens section 4a is formed on a flat surface glass substrate by, for example, the reflow method (which is a method for using photolithography to form a circular-cylindrical resist pattern to heat the glass substrate to flow photoresist so that a lens shape is processed by the surface tension). The manufacture method of the image pickup lens section 4a is not limited to this. For example, the ink jet method also may be used by which an ink jet printer head is used to drop a minute amount of resin material on predetermined positions to form a lens shape by the surface tension.

Alternatively, instead of directly forming a lens shape, a flat plate lens formed by the ion exchange method for example also may be used. The ion exchange method forms, on a mask on a glass substrate, a pinhole suitable for a lens to diffuse ion from this pinhole so that a three-dimensional change of the refractive index is caused in a stepwise manner by the ion exchange and thermal diffusion.

When the image pickup lens section 4a is formed to have an aspheric surface, a method may be used that is similar to a method for manufacturing a hybrid aspheric surface lens in which a glass used for a camera lens or the like is integrated with resin for example. When a camera lens is formed, an aspheric surface of UV cure-type resin is formed on a glass spherical surface. However, in the present invention, UV cure-type resin is dropped on a flat surface glass substrate to mold the resin in an aspheric surface mold to have a desired shape to subsequently subject the resin to UV curing. As a result, the seal member 4 having the image pickup lens section 4a having an aspheric surface can be manufactured.

The infrared ray cut filter coating 5 is provided on a photoelectric conversion section side face 4c of the seal member 4 by a coating method (e.g., vacuum deposition) so that the infrared ray cut filter coating 5 is integrated with the seal member 4. The solid-state image pickup device 10 also may be structured so that at least a part of the image pickup lens section 4a of the seal member 4 is formed by an infrared ray absorption member to provide an infrared ray cut function.

An aperture stop 6 consists of a member that blocks visible light contributing to an image formation and defines an F number of the image pickup lens section 4a. In this embodiment, the aperture stop 6 is integrated with the seal member 4 by a painting method or a coating method (e.g., vacuum deposition).

The solid-state image pickup device 10 of this embodiment is fixed to an electronic substrate (not shown) by soldering the electrode 1a. Via this electrode 1a, a signal subjected to the photoelectric conversion by the photoelectric conversion section 2a can be outputted to a predetermined circuit on the electronic substrate and a voltage or clock from an external circuit for driving the solid-state image pickup device 10 can be received. When the solid-state image pickup device 10 is the CMOS-type one including a signal processing circuit, the electrode will output an image signal (e.g., a YUV signal (Y denotes a brightness signal, U(=R−Y) denotes a color difference signal between red and a brightness signal, V(=B−Y) denotes a color difference signal between blue and a brightness signal)).

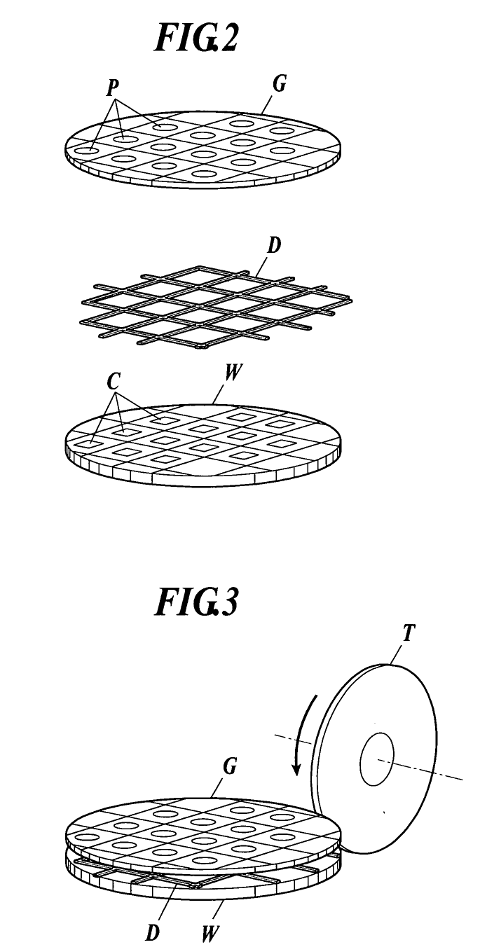

FIG. 2 illustrates the manufacture steps (the former stage) of the solid-state image pickup device 10. FIG. 3 illustrates the manufacture steps (the latter stage) of the solid-state image pickup device.

In FIG. 2, on one face of a disk-like wafer W (silicon substrate 1), a plurality of semiconductor devices C having photoelectric conversion section 2a or the like are formed by a semiconductor preparation process. On the other face of the wafer W, a plurality of electrodes 1a are formed. On the other hand, a photoresist P is formed, by a method such as photolithography, on a disk-like glass substrate G (seal member 4) so that the photoresist P is opposed to the semiconductor device C of the wafer W. Thereafter, the image pickup lens section 4a is formed by the reflow method.

Thereafter, the aperture stop 6 is painted or formed by a coating method (e.g., vacuum deposition) on the upper part of the image pickup lens section 4a. The infrared ray cut filter coating 5 is also painted or formed by a coating method (e.g., vacuum deposition) on the lower part of the image pickup lens section 4a. It is noted that the aperture stop 6 in the glass substrate G may include a film having a light blocking property at the exterior thereof.

Thereafter, the glass substrate G is adhered to the wafer W so that, while allowing the wafer W and the glass substrate G to sandwich lattices D, the glass substrate G seals the semiconductor device C. As a result, these glass substrate G, lattices D, and wafer W are integrated.

Then, the integrated wafer W, lattices D, and glass substrate G are diced by a dicing tool T as shown in FIG. 3. Then, the diced members are formed as the individual solid-state image pickup devices as shown in FIG. 1. The dicing tool T cuts the center of the frames of the lattices D so that, when the solid-state image pickup devices are separated as chips, spacer members 3 are formed by the cut lattices D.

In this embodiment, the lens-attached solid state image pickup devices is obtained when the dicing step (separation step) is completed. Thus, the productivity is high and high-quality products can be produced in a great amount. This embodiment also can maintain the parallelism between the wafer W and the glass substrate G to be high. This also allows, in the solid-state image pickup devices cut out via the dicing, a parallelism between the seal member 4 and the semiconductor device 2 to be high.

### Modified Embodiment 1

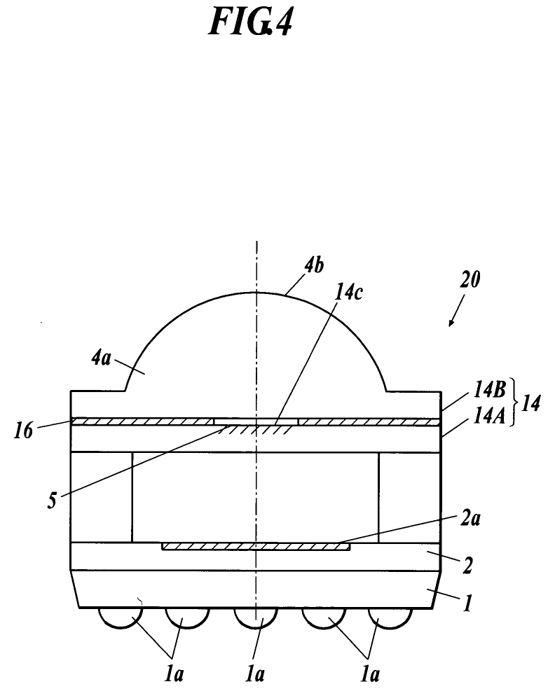

FIG. 4 illustrates a modified embodiment of the solid-state image pickup device 10 of FIG. 1 (solid-state image pickup device 20).

In the solid-state image pickup device 20 according to Modified Embodiment 1, a seal member 14 is composed of a plurality of components. Specifically, the seal member 14 is composed of a parallel flat plate 14A which is supported by the spacer member 3, an optical device 14B having an image pickup lens section 4a, and a doughnut plate-like aperture stop 16 which provided between the parallel flat plate 14A and the optical device 14B. The infrared ray cut filter coating 5 is formed on the image pickup lens side face 14c of the parallel flat plate 14A. The solid-state image pickup device 20 has the same structure as that of the embodiment of FIG. 1 except for the above. Thus, the same structure will not be further described by denoting the same components with the same reference numerals.

### Modified Embodiment 2

FIG. 5 illustrates Modified Embodiment 2 of the solid-state image pickup device 10 of FIG. 1 (solid-state image pickup device 30).

As in the solid-state image pickup device 20 according to Modified Embodiment 1, the solid-state image pickup device 30 according to Modified Embodiment 2 also has the seal member 14 composed of a plurality of members. Specifically, the seal member 14 is composed of the parallel flat plate 14A, a second parallel flat plate 14C, and the aperture stop 16.

The solid-state image pickup device 20 according to Modified Embodiment 1 has the optical device 14B integrated with the image pickup lens section 4a. The solid-state image pickup device 30 according to Modified Embodiment 2 is different from the solid-state image pickup device 20 in that the second parallel flat plate 14C is separately provided from the solid image pickup lens section 4a. The solid-state image pickup device 30 has the same structure as those of the embodiments of FIG. 1 and FIG. 4 except for the above. Thus, the same structure will not be further described by denoting the same components with the same reference numerals.

When considering which of the solid-state image pickup devices 10, 20 and 30 is used in the present invention, in order to correct aberrations in a favorable manner with the image pickup lens section 4a having only one optical surface 4b, the solid-state image pickup devices 20 and 30 of FIGS. 4 and 5 in which the aperture stop 16 is away from the refracting surface (optical surface 4b) are more desirable than the solid-state image pickup device 10 of FIG. 1 in which the aperture stop 6 is close to the refracting surface (optical surface 4b). The reason is that, when the solid-state image pickup devices 20 and 30 of FIGS. 4 and 5 are compared with the solid-state image pickup device 10 of FIG. 1, on-axis ray and off-axis ray of the solid-state image pickup devices 20 and 30 pass a refracting surface at different heights and thus the aspheric surface can be effectively used to increase the freedom degree of the aberration correction.

### EXEMPLARY EXAMPLES

The following exemplary examples show actual data when a solid-state image pickup device corresponding to the solid-state image pickup device 30 of FIG. 5 is used.

Marks used in this exemplary example have the following meanings.

f: Focal length of the entire system of an image pickup lens

fB: Back focus

F: F number

2Y: Length of a diagonal line of a rectangular effective pixel region of a solid-state image pickup device

R: Curvature radius

D: Distance between on-axis faces

Nd: Refractive index to a line d of lens material

νd: Abbe number of lens material

In Exemplary Examples 1 and 2 shown below, the shape of an aspheric surface is represented by the following formula on the assumption that an apex of the face is an origin, an optical axis direction is along an axis X, and a height in a direction vertical to the optical axis is

[Formula 1]

$$X = \frac{{h}^{2} / R}{1 + \sqrt{1 - ( 1 + K ) {h}^{2} / {R}^{2}}} + \sum {A}_{i} {h}^{i}$$

Ai: ith aspheric surface coefficient
R: curvature radius
K: conic constant

### Exemplary Example 1

Exemplary Example 1 uses two glass substrates separated from one another as members corresponding to the parallel flat plate 14A and the second parallel flat plate 14C of FIG. 5. An image pickup lens section made of resin material is formed on a glass substrate. The respective glass substrates have therebetween an aperture stop. Data for this structure is shown below.

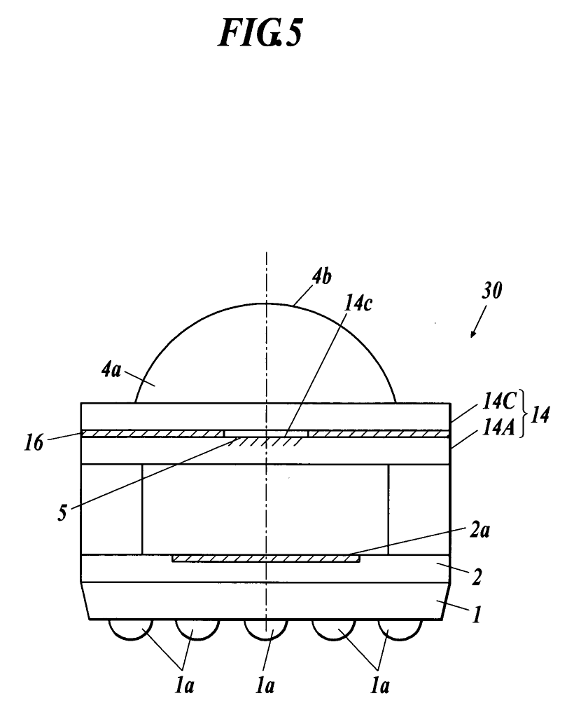

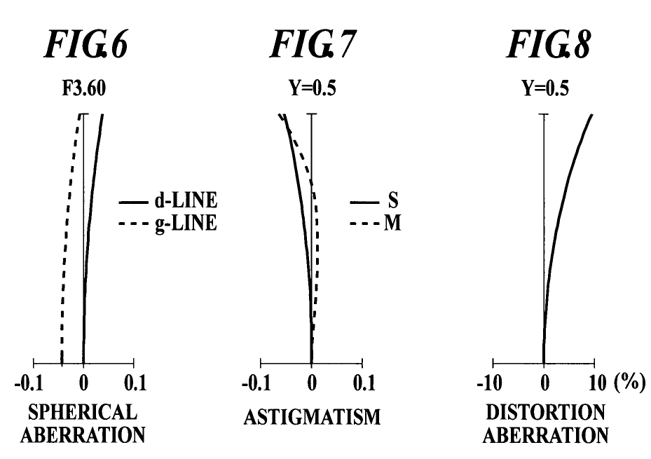

Tables 1 and 2 shown below show the data for this image pickup lens section. FIG. 6 to FIG. 8 show abberrations of the image pickup lens section.

TABLE 1

f = 0.841 mm, F = 3.60, 2Y = 1.00 mm, fB = 0.450 mm
(Object distance = 300 mm)

| Face No. | R(mm) | D(mm) | Nd | νd |
|---|---|---|---|---|
| 1 | 0.549 | 0.18 | 1.65300 | 22.3 |
| 2 | ∞ | 0.20 | 1.51633 | 64.1 |
| 3 | ∞ | 0.02 | | |
| stop | ∞ | 0.00 | | |
| 4 | ∞ | 0.20 | 1.51633 | 64.1 |
| 5 | ∞ | | | |

In Table 1, “face No. 1” denotes an object side face of a part corresponding to the image pickup lens section 4a of FIG. 5, “face No. 2” denotes an image side face of this part, “face No. 3” denotes an image side face of a glass substrate corresponding to the second parallel flat plate 14C of FIG. 5, “face No. 4” denotes an object side face of a glass substrate corresponding to the parallel flat plate 14A of FIG. 5, and “face No. 5” denotes an image side face of the glass substrate.

TABLE 2
Aspheric surface coefficients of the first face

| | |
|---|---|
| K = | 1.08340E+00 |
| A4 = | −2.55580E+00 |
| A6 = | −2.35340E+01 |
| A8 = | 3.32470E+02 |
| A10 = | −2.02890E+03 |

Data of aspheric surface coefficients in Table 2 is represented with an exponential in decimal of “E”. For example, “2.5×10⁺²” is represented as “2.5E+02”.

### Exemplary Example 2

Exemplary Example 2 also uses two glass substrates separated from one another as members corresponding to the parallel flat plate 14A and the second parallel flat plate 14C of FIG. 5. An image pickup lens section made of resin material is formed on a glass substrate. The respective glass substrates have an aperture stop therebetween. Data for this structure is shown below.

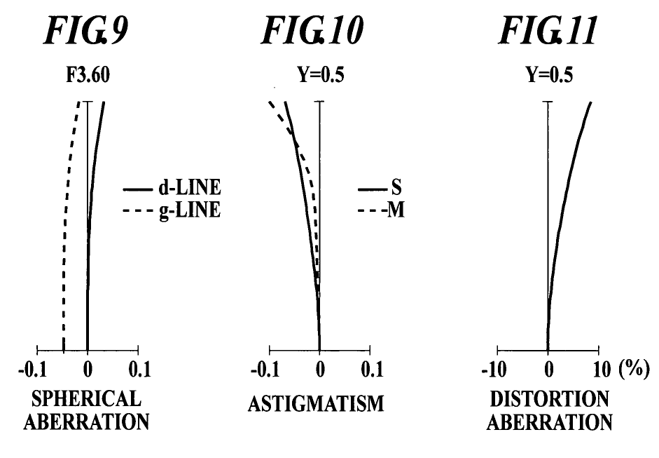

Tables 3 and 4 shown below show the data for this image pickup lens section. FIG. 9 to FIG. 11 show aberrations of the image pickup lens section.

TABLE 3

f = 0.919 mm, F = 3.60, 2Y = 1.00 mm, fB = 0.517 mm
(Object distance = 300 mm)

| Face No. | R(mm) | D(mm) | Nd | νd |
|---|---|---|---|---|
| 1 | 0.600 | 0.20 | 1.65300 | 22.3 |
| 2 | ∞ | 0.20 | 1.51633 | 64.1 |
| 3 | ∞ | 0.02 | | |
| stop | ∞ | 0.00 | | |
| 4 | ∞ | 0.20 | 1.51633 | 64.1 |
| 5 | ∞ | | | |

In Table 3, “face Nos. 1 to 5” have the same meanings as those of “face Nos. 1 to 5” of Table 1.

TABLE 4
Aspheric surface coefficients of the first face

| | |
|---|---|
| K = | 1.37840E+00 |
| A4 = | −1.22010E+00 |
| A6 = | −5.79700E+01 |
| A8 = | 9.67450E+02 |
| A10 = | −5.89860E+03 |

As in Table 2, data of aspheric surface coefficients in Table 4 is also represented with an exponential in decimal of “E”.

Although Exemplary Examples 1 and 2 have a structure in which an aperture stop is formed between two glass substrates, the aperture stop also may be provided by coating, vapor deposition or the like on a glass substrate on which an image pickup lens section is formed. Furthermore, Exemplary Examples 1 and 2 also may have a structure in which, in order to correct aberration in a more favorable manner, image pickup lens sections are formed on glass substrates at both sides of the aperture stop.

As described above, the present invention has been described with reference to the embodiments and exemplary examples. However, the present invention should not be interpreted as being limited to the above embodiments and exemplary examples. Thus, the present invention may be appropriately changed or modified.

The entire disclosure of Japanese Patent Application No. Tokugan 2005-111864 filed on Apr. 8, 2005 including specification, claims drawings and summary are incorporated herein by reference in its entirety.

What is claimed is:

1. A solid-state image pickup device comprising:
a photoelectric conversion section formed on one face of a silicon substrate, a seal member for sealing the photoelectric conversion section, and an electrode for sending and receiving an electric signal,
wherein the seal member comprises an image pickup lens section for causing the photoelectric conversion section to form an object image; and
the electrode is formed on a face different from the one face of the silicon substrate.

2. The solid-state image pickup device of claim 1, wherein the seal member is provided on the silicon substrate via a spacer member provided around the photoelectric conversion section.

3. The solid-state image pickup device of claim 2, wherein the seal member is integrated with an aperture stop and/or an infrared ray cut filter coating.

4. The solid-state image pickup device of claim 1, wherein the solid-state image pickup device is manufactured by simultaneously forming a plurality of solid-state image pickup devices on the silicon substrate to subsequently subject the devices to a dicing step to separate the devices as chips.

5. The solid-state image pickup device of claim 1, wherein the seal member has a glass transition temperature Tg of 200° C. or more.

6. The solid-state image pickup device of claim 1, wherein the image pickup lens section has an aspheric surface shape in which a face closest to an object has a convex surface toward the object and the other faces have a flat surface shape.

7. A method for manufacturing a plurality of solid-state image pickup devices, each of the solid-state image pickup devices comprising a photoelectric conversion section, an image pickup lens section for causing the photoelectric conversion section to form an object image and an electrode for sending and receiving an electric signal, comprising:
forming a plurality of the photoelectric conversion sections on one face of a silicon substrate;
forming the electrode on a face different from the one face of the silicon substrate;
forming seal members having a plurality of the image pickup lens sections, via lattice-shaped spacer members provided around each of the photoelectric conversion sections, on the one face of the silicon substrate so as to seal the photoelectric conversion sections; and
cutting the silicon substrate, the spacer members and the seal members which are integrated, at the lattice frames of the spacer members.

8. The manufacture method of the solid-state image pickup device of claim 7, comprising forming a coating of an infrared ray cut filters on the seal members.

9. The manufacture method of the solid-state image pickup device of claim 7, comprising forming a film having a light blocking property at an exterior of an aperture stop on the seal members.

10. The manufacture method of the solid-state image pickup device of claim 7, wherein the image pickup lens section has an aspheric surface shape in which a face closest to an object has a convex surface toward the object and the other faces have a flat surface shape.
